(19) United States
(12) Patent Application Publication
(10) Pub. No.: US 2014/0009296 A1
(43) Pub. Date: Jan. 9, 2014

(54) TEST APPARATUS TO ESTABLISH LOCATIONS OF ELECTRICAL SHORT CIRCUITS

(71) Applicants: Hon Hai Precision Industry Co., Ltd., New Taipei (TW); Hong Fu Jin Precision Industry (Shenzhen) Co., Ltd., Shenzhen (CN)

(72) Inventors: JIA LI, Shenzhen (CN); JUN LI, Shenzhen (CN)

(21) Appl. No.: 13/935,512

(22) Filed: Jul. 4, 2013

(30) Foreign Application Priority Data
Jul. 6, 2012 (CN) 2012102330223

(51) Int. Cl. G01R 31/02; G08B 21/18

(52) U.S. Cl. CPC G01R 31/025; G08B 21/185
USPC 340/650; 324/527

(57) ABSTRACT

A test apparatus for testing for short circuits in electrical wiring comprises an emission apparatus and a detection apparatus. The emission apparatus provides a test signal into the electrical wiring, where the test signal is adjustable both for frequency and amplitude. An electromagnetic field is generated in and around the wiring under test. The detection apparatus amplifies strength of magnetic fields found, and detects electromagnetic fields caused by the test signal in a circuit loop. When a signal confirming detection drops suddenly in strength by more than a predetermined threshold, a point or portion of the wiring under the detector is established as a point of short circuit.

### BACKGROUND

1. Technical Field

The present disclosure relates to test technologies, and more particularly to a test apparatus to establish location of electrical short circuits.

2. Description of Related Art

Electronic wires are usually located at a hidden place, such as under a wall, or under a floor. When an electrical short is found, an oscilloscope is used to test impedance of the electronic wire to find a position of the short circuit. The impedance of the electronic wire from a test point to the location of short circuit is obtained, then the impedance is compared with an impedance table, and a ratio of the length of electronic wire from the test point to the location of short circuit to a total length of electronic wire is estimated. However, the electronic wire is often located in irregular and non-geometric paths. The test process is time-consuming, and a result of the test is imprecise. Therefore, there is room for the improvement in the art.

### BRIEF DESCRIPTION OF THE DRAWINGS

The components in the drawings are not necessarily drawn to scale, the emphasis instead placed upon clearly illustrating the principles of at least one embodiment. In the drawings, like reference numerals designate corresponding parts throughout the various views, and all the views are schematic.

FIG. 1 is a block diagram of test apparatus according to an exemplary embodiment of present disclosure.

FIG. 2 is a circuit diagram of one embodiment of an emission apparatus of the test apparatus of FIG. 1.

FIG. 3 is a circuit diagram of one embodiment of a first voltage converting circuit of the test apparatus of FIG. 1.

FIG. 4 is a circuit diagram of one embodiment of a second voltage converting circuit of the test apparatus of FIG. 1.

FIG. 5 is a circuit diagram of one embodiment of a detection apparatus of the test apparatus of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

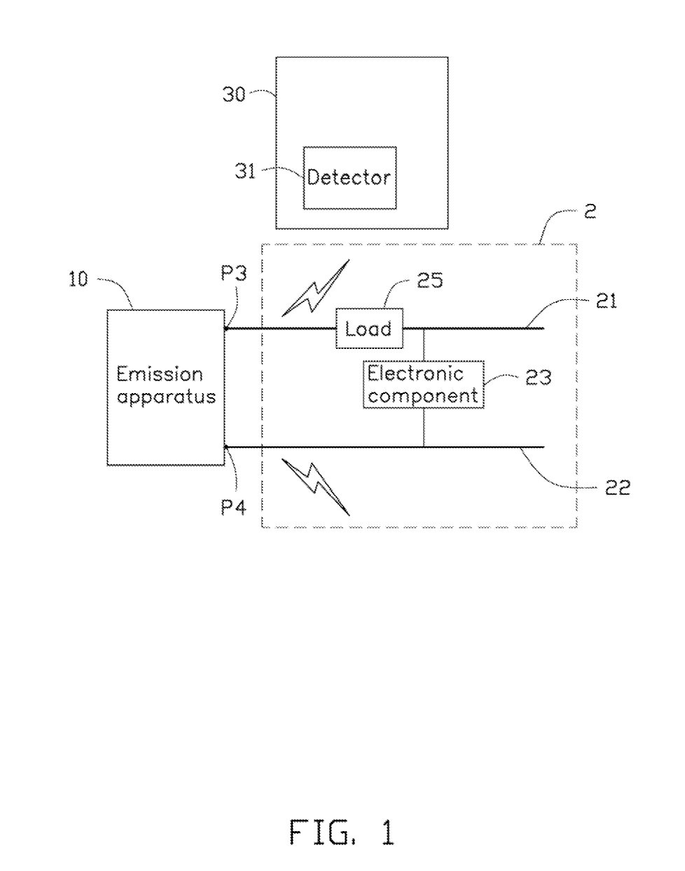

FIG. 1 is a block diagram of test apparatus according to an exemplary embodiment of present disclosure. The test apparatus 1 is configured to move along an electronic wire 2 and test a location of short circuit at which conduction of electricity is significantly reduced (short point) as an indication of a short-circuit situation, caused by a malfunctioning component, or damage to the wire. The test apparatus 1 includes an emission apparatus 10 and a detection apparatus 30. The emission apparatus 10 is electrically coupled to two terminals of the electronic wire 2, and provides a test signal to the electronic wire 2. The two terminals of the electronic wire 2 are one end P3 of a first electronic wire 21 and one end P4 of a second electronic wire 22 as shown in FIG. 1. When the test signal is transmitted via the electronic wire 2, an electromagnetic field is accordingly generated in and around the electronic wire 2. The detection apparatus 30 includes a detector 31, which is configured to detect the electromagnetic field, and to generate a signal accordingly. When the signal shows a drop in strength of the electromagnetic field, and an extent of the drop is more than a predetermined threshold, a portion of the electronic wire 2 where the detector 31 detects the drop in strength is regarded as a location of a short circuit t of the electronic wire 2.

In the embodiment, the electronic wire 2 includes a first electronic wire 21 and a second electronic wire 22. An electronic component 23 and a load 25 are electrically coupled in parallel between the first electronic wire 21 and the second electronic wire 22 to form a circuit. The emission apparatus 10 includes a first testing terminal P3 and a second testing terminal P4. The first testing terminal P3 is electrically coupled to one end of the first electronic wire 21, and the second testing terminal P4 is electrically coupled to one end of the second electronic wire 22.

When the electronic component 23 is electrically shorted, the test signal passes from the emission apparatus 10, the first testing terminal P3, the load 25, the electronic component 23, and the second testing terminal P4 to form a loop. The test signal is only transmitted through the loop. Test signal can not transmitted through the electronic wire 2 outside the loop, because of the short circuit. Thus, the electromagnetic field is only generated within the loop, but because no test signal passes through the electronic wire 2 which leads outside the loop, the electromagnetic field generated outside and beyond the loop is weak. When detecting the location of the short circuit, the detector 31 of the detection apparatus 30 is moved along the electronic wire 2. The detection apparatus 30 detects the electromagnetic field generated by the test signal passing through the electronic wire 2, and generates a signal according to the electromagnetic field. When the detector 31 is at a point where the obtained signal drops sharply and decreases to less than a predetermined threshold, that point is determined to be a location of a short circuit of the electronic wire 2. That is, when the detector 31 detects a decrease in intensity of the testing signal, along the electronic wire 2 is greater than a predetermined threshold, the short circuit location of the electronic wire 2 is determined.

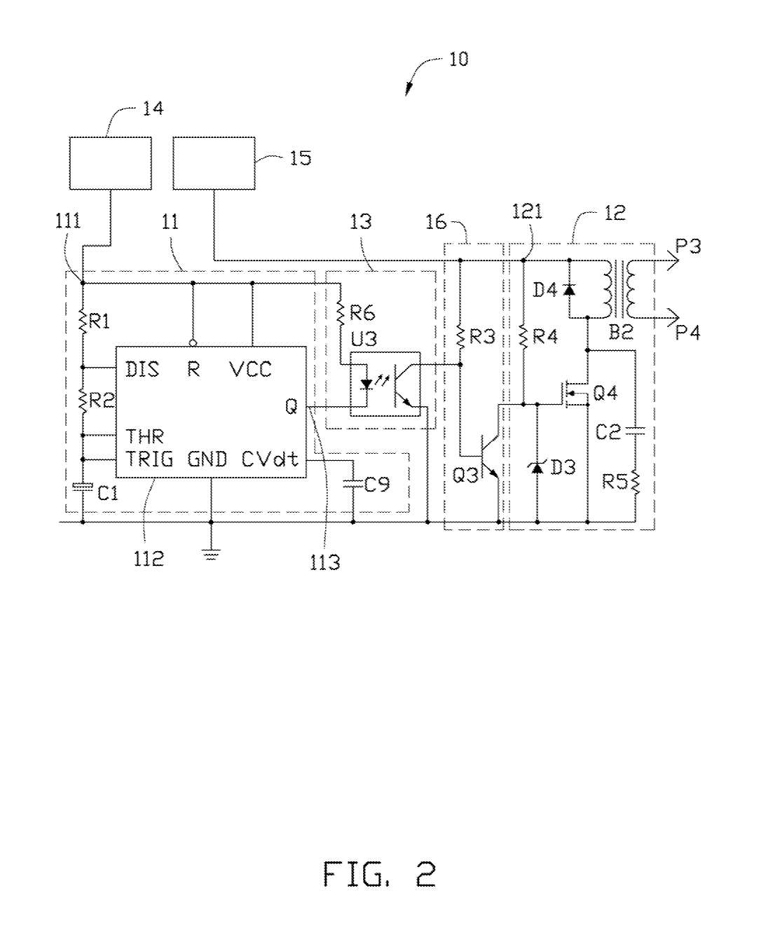

FIG. 2 is a circuit diagram of one embodiment of an emission apparatus of the test apparatus of FIG. 1. The emission apparatus 10 includes a signal generating circuit 11, a light-coupling and isolating circuit 13, an inverting and amplifying circuit 16, a first power amplifying circuit 12, a first voltage converting circuit 14 and a second voltage converting circuit 15.

The first voltage converting circuit 14 generates a first direct current (DC) voltage, and the first DC voltage is provided to the signal generating circuit 11. The second voltage converting circuit 15 is electrically coupled to the first power amplifying circuit 12, and generates a second DC voltage. The second DC voltage is provided to the first power amplifying circuit 12. The value of the second DC voltage is adjustable, to change detection sensitivity of the test apparatus 1.

The signal generating circuit 11 generates a rectangular pulse according to the first voltage. The light-coupling and isolating circuit 13 couples the rectangular pulse to the inverting and amplifying circuit 16. The inverting and amplifying circuit 16 converts the rectangular pulse into a narrow pulse. The narrow pulse has an inverting phase of the rectangular pulse, and is provided to the electronic wire 2.

In the embodiment, the signal generating circuit 11 includes a first voltage input terminal 111, a first resistor R1, a second resistor R2, a first capacitor C1, a first integrated chip 112, and a pulse output terminal 113.

The first voltage input terminal 111 receives the first DC voltage output from first voltage converting circuit 14. The first resistor R1, the second resistor R2, and the first capacitor C1 are electrically coupled in series between the first voltage input terminal 111 and ground.

The first integrated chip 112 includes a trigger terminal TRIG, a discharge terminal DIS, and an output terminal Q which is defined as the pulse output terminal 113. The discharge terminal DIS is electrically coupled to a node between the first resistor R1 and the second resistor R2. The trigger terminal TRIG is electrically coupled to a node between the second resistor R2 and the first capacitor C1. The first capacitor C1 is charged by the first DC voltage via the first resistor R1 and the second resistor R2, and the charge time of the first capacitor C1 is defined as a first time period. The first capacitor C1 discharges via the second resistor R2 and the discharge terminal DIS, and the discharging time of the first capacitor C1 is defined as a second time period. There is a high level voltage (logic 1) continuously in the first time period and a low level voltage (logic 0) continuously in the second time period. The first capacitor C1 is charged and is discharged periodically. Thus, the rectangular pulse has a waveform that continuously and periodically swings between a high level (logic 1) and a low level (logic 0), and is generated by the generating circuit 11 and output via the pulse output terminal 113. In the waveform of the rectangular pulse, the continuous output time of the high level of the rectangular pulse corresponds to the first time period, the continuous output time of the low level of the rectangular pulse corresponds to the second time period, and the first time period is greater than the second time period.

The light coupler U3 isolates the signal generating circuit 11 from the first transformer B2 and thus against damage accordingly. The light-coupling and isolating circuit 13 includes a sixth resistor R6, and a light coupler U3. The light coupler U3 includes a light emitting block and a light receiving block. A terminal of the light emitting block is electrically coupled to the sixth resistor R6, and receives the second DC voltage. The other terminal of the light emitting block is electrically coupled to the pulse output terminal 113, and serves as an input terminal of the light-coupling and isolating circuit 13 to receive the rectangular pulse. The light emitting block converts the rectangular pulse into an optical signal. The light receiving block receives the optical signal and converts the optical signal into a rectangular pulse. In the embodiment, the light coupler U3 can be for example an optical coupling triode.

The inverting and amplifying circuit 16 includes a bipolar junction transistor (BJT) Q3 as a transistor, and a third resistor R3. The BJT Q3 includes an emitter, a base, and a collector. The emitter of the BJT Q3 is grounded, the base of the BJT Q3 is electrically coupled to the light receiving block of the light-coupling and isolating circuit 13 to receive the rectangular pulse output from the coupler U3. One end of the third resistor R3 is electrically coupled to the base of the BJT Q3, and the other end of the third resistor R3 is electrically coupled to the second voltage converting circuit 15 to receive the second DC voltage. The BJT Q3 converts the rectangular pulse to generate a narrow pulse. The narrow pulse is an inverting phase of the rectangular pulse, that is, the continuous high level time the narrow pulse is the second time period, and the continuous low level time of the narrow pulse is the first time period. The narrow pulse is output via the collector of the BJT Q3. The narrow pulse has a high instantaneous current but a low average current. The heat energy generated by the narrow pulse passing through the electronic wire 2 is proportional to the square of the average current of the narrow pulse. Thus, the utilization of a narrow pulse avoids damage to the electronic wire 2.

The first power amplifying circuit 12 includes a second DC voltage input terminal 121, a first transformer B2, a field-effect transistor (FET) Q4, a fourth resistor R4, a Zener diode D3, a diode D4, a fifth resistor R5 and the second capacitor C2.

The second DC voltage input terminal 121 is electrically coupled to the second voltage converting circuit 15 and receives the second DC voltage.

The first transformer B2 includes a primary coil and a secondary coil. The FET Q4 includes a source, a drain and a gate. One end of the fourth resistor R4 is electrically coupled to the second DC voltage input terminal 121, and the other end of the resistor R4 is electrically coupled to the gate of the FET Q4. One end of the primary coil of the first transformer B2 is electrically coupled to the second DC voltage input terminal 121. The source of the FET Q4 and the drain of the FET Q4 are electrically coupled in series between the other end of the primary coil of the first transformer B2 and ground. The gate of the FET Q4 is electrically coupled to the collector of the BJT Q3. The gate of the FET Q4 receives the narrow pulse, and the narrow pulse controls the FET Q4 to be switched on or switched off. In detail, the high level portion of the narrow pulse controls the FET Q4 to be switched on, and the low level portion of the narrow pulse controls the FET Q4 to be switched off. The narrow pulse is amplified by the first power amplifying circuit 12, and is coupled from the primary coil of the transformer B2 to the secondary coil of the transformer B2 to form the test signal. The two terminals of the secondary of the first transformer B2 are electrically coupled to the electronic wire 2 to output the test signal to the electronic wire 2. A frequency of the test signal is not the same as a typical frequency used in an AC power gate, such as 50 HZ or 60 HZ. In the embodiment, the frequency of the test signal is 400 HZ, but the disclosure is not limited thereto.

The Zener diode D3 includes a cathode and an anode. The cathode of the Zener diode D3 is electrically coupled to the gate of the FET Q4. The anode of the Zener diode D3 is grounded. The Zener diode D3 is a protective component of the gate of the FET Q4.

The diode D4 is connected in parallel with the secondary coil of the first transformer B2, and a cathode of the diode D4 is electrically coupled to the second DC voltage input terminal 121. The diode Q4 serves as a protecting component of the FET Q4, to avoid damage from the first transformer B2 due to a sudden voltage being applied when the FET Q4 is switched off.

The second capacitor C2 and the fifth resistor R5 are electrically coupled in series between the source of the FET Q4 and ground. The second capacitor C2 and the fifth resistor R5 absorb a peak pulse generated by the secondary coil of the first transformer B2.

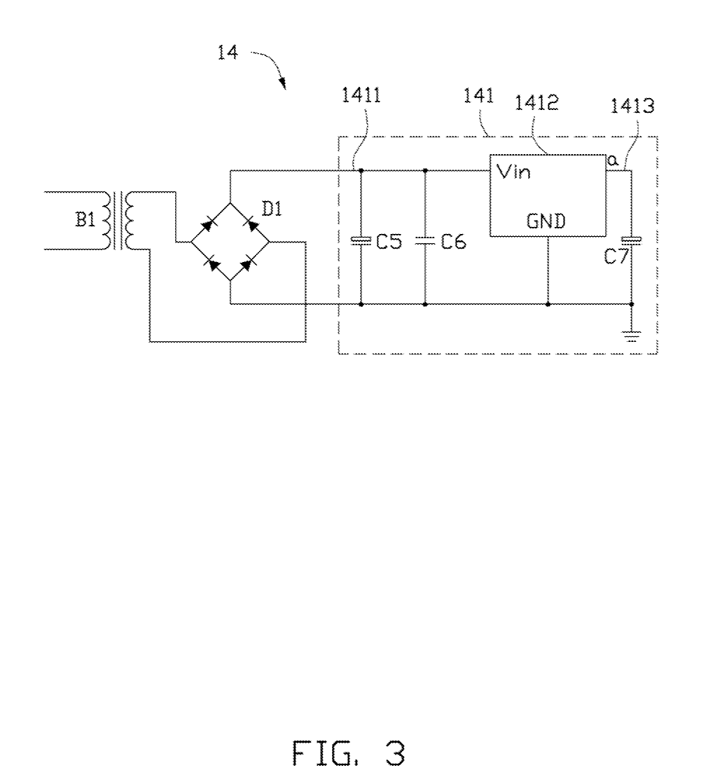

FIG. 3 is a circuit diagram of one embodiment of a first voltage converting circuit of the test apparatus of FIG. 1. The first voltage converting circuit 14 includes a second transformer B1, a first bridge rectifier D1, and a regulating block 141.

The second transformer B1 includes a primary coil and a secondary coil. The primary coil of the second transformer B1 receives a first alternating current (AC) voltage. The second transformer B1 converts the first AC voltage into a second AC voltage, and outputs the second AC voltage via the secondary coil of the second transformer B1. A voltage value of the second AC voltage is less than that of the first AC voltage. In one embodiment, the first AC voltage is 220V.

An input terminal of the first bridge rectifier D1 is connected in parallel with the secondary coil of the second transformer B1 to receive the second AC voltage. The first bridge rectifier D1 converts the second AC voltage into an original DC voltage. The original DC voltage is output via the output terminals of the first bridge rectifier D1.

The regulating block 141 includes a regulating input terminal 1411, a regulator 1412, a fifth capacitor C5, a sixth capacitor C6, a seventh capacitor C7, and a regulating output terminal 1413. The regulating input terminal 1411 is electrically coupled to one of the output terminals of the first bridge rectifier D1. The other output terminal of the first bridge rectifier D1 is electrically coupled to ground. The regulating block 141 rectifies the original DC voltage received by the regulating input terminal 1411, and converts the original DC voltage into a first direct current (DC) voltage. The first DC voltage is output via the regulating output terminal 1413. In one embodiment, the first DC voltage is 12V.

The regulator 1412 includes an input terminal Vin, a ground terminal, and an output terminal “a.” The input terminal Vin is electrically coupled to the regulating input terminal 1411. The ground terminal is grounded. The output terminal “a” is electrically coupled to the regulating output terminal 1413. The fifth capacitor C5 is connected in parallel with the six capacitor C6 and ground. The seventh capacitor C7 is electrically between the output terminal “a” and ground.

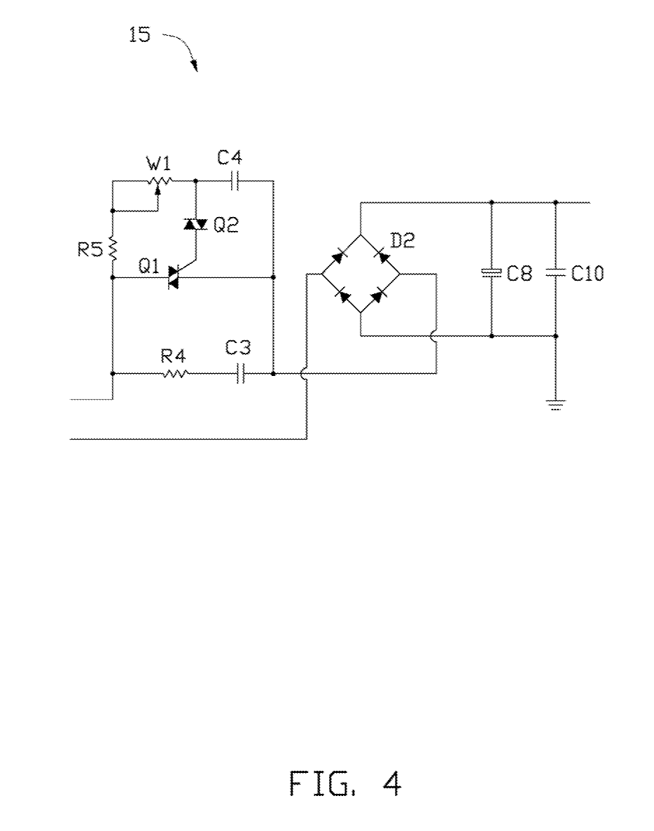

FIG. 4 is a circuit diagram of one embodiment of a second voltage converting circuit of the test apparatus of FIG. 1. The second voltage converting circuit 15 includes a fourth resistor R4, a third capacitor C3, a first bidirectional silicon-controlled rectifier Q1, a fifth resistor R5, a rheostat W1, a fourth capacitor C4, a second bidirectional silicon-controlled rectifier Q2, a second bridge rectifier D2, a eighth capacitor C8, and a tenth capacitor C10.

The second bridge rectifier D2 includes two input terminals. One input terminal of the second bridge rectifier D2 is electrically coupled with the third capacitor C3 and the fourth resistor R4 in series. The other input terminals of the second bridge rectifier D2 is connected to a terminal of the fourth resistor R4 away from the third capacitor C3 and serves as input terminals of a third AC voltage. The first bidirectional silicon-controlled rectifier Q1 is connected in parallel with a circuit branch formed by the fourth resistor R4 and the third capacitor C3. The fifth resistor R5 is electrically coupled with the rheostat W1 and the fourth capacitor C4 to form another circuit branch which is connected in parallel with the first bidirectional silicon-controlled rectifier Q1. One terminal of the second bidirectional silicon-controlled rectifier Q2 is electrically coupled between a node between the rheostat W1 and the fourth capacitor C4, and the other terminal is connected to a node between the first bidirectional silicon-controlled rectifier Q1 and the third capacitor C3. The eighth capacitor C8 and the tenth capacitor C9 are electrically coupled to the output terminals of the second bridge rectifier D2. One of the output terminals of the second bridge rectifier D2 is grounded.

The rheostat W1 rectifies a voltage value of the third AC voltage. The second bridge rectifier D2 receives the third AC voltage, converts the third AC voltage into a second direct current (DC) voltage, and outputs the second DC voltage to the first power amplifying circuit 12.

The second voltage converting circuit 15 generates a second DC voltage, and the voltage value of the second DC voltage is adjustable. The testing sensitivity of the test apparatus 1 is changed according to the voltage value of the second DC voltage.

In detail, the electromagnetic field generated by a voltage passing through an electronic wire 2 is proportional to the voltage value. Thus, if the electronic wire 2 is far or at greater depth from the immediate area being investigated, the second voltage converting circuit 15 improves the voltage value of the second DC voltage to improve the testing sensitivity of the test apparatus 1. Otherwise, if the electronic wire 2 is near the immediate area which is under test, the second voltage converting circuit 15 reduces the voltage value of the second DC voltage to reduce the test sensitivity of the test apparatus 1, to save energy.

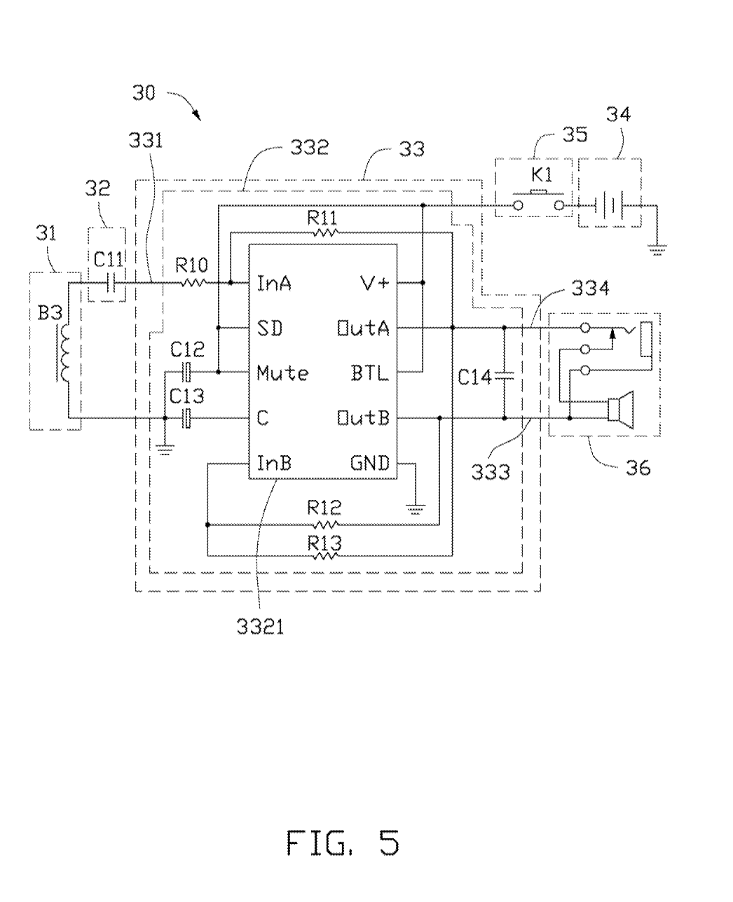

FIG. 5 is a circuit diagram of one embodiment of a detection apparatus of the test apparatus of FIG. 1. The detection apparatus 30 includes a detector 31, a frequency selecting circuit 32, a signal amplifying circuit 33, a first source 34, a switch 35 and a loudspeaker 36.

The detector 31 detects an electromagnetic field and generates a signal accordingly. In one embodiment, the detector 31 is a coil having an iron core. One output terminal of the detector 31 is electrically coupled to the frequency selecting circuit 32, and the other output terminal of the detector 31 is grounded.

The frequency selecting circuit 32 selects the signal which confirms detection to have the same frequency as the test signal, to improve the test sensitivity of the detection apparatus 30. A signal confirming detection which has the same frequency as the test signal is defined as a first detecting signal. In one embodiment, the frequency selecting circuit 32 is a capacitor C11.

The signal amplifying circuit 33 includes a signal input terminal 331, a signal amplifying block 332, a first signal output terminal 334, and a second signal output terminal 333. The signal input terminal 331 is electrically coupled to the frequency selecting circuit 32, to receive the first detecting signal. The signal amplifying block 332 amplifies the first detecting signal into a second detecting signal. The signal amplifying block 332 is hereafter described in detail.

The signal amplifying block 332 includes a tenth resistor R10, a second integrated chip 3321, an eleventh resistor R11, a twelfth resistor R12, a thirteenth resistor R13, a twelfth capacitor C12, a thirteenth capacitor C13, and a fourteenth capacitor C14. The second integrated chip 3321 includes a first input terminal InA, a second input terminal InB, a module selecting terminal Mute, a capacitor connecting terminal C, a source input terminal V+, a first output terminal OutA, a second output terminal OutB, a terminal SD, a sound mode selecting terminal BTL, and a ground terminal GND.

The tenth resistor R10 is electrically coupled between the first input terminal InA of the second integrated chip 3321 and the signal input terminal 331. The eleventh resistor R11 is electrically coupled between the first input terminal InA and the first output terminal OutA. The twelfth resistor R12 is electrically coupled between the second input terminal InB and the second output terminal OutB. The thirteenth resistor R13 is electrically coupled between the second input terminal InB and the first output terminal OutA. The twelfth capacitor C12 is electrically coupled between the mode selecting terminal Mute and ground. The thirteenth capacitor C13 is electrically coupled between the capacitor connecting terminal C and ground. The fourteenth capacitor C14 is electrically coupled between the first output terminal OutA and the second output terminal OutB. The fourteenth capacitor C14 reduces spontaneous high frequency signal generated by the second integrated chip 3321. The terminal SD is electrically coupled between a node between the mode selecting terminal Mute and the switch 35. The source input terminal V+ is electrically coupled between a node between the switch 35 and the sound mode selecting terminal BLT. The first output OutA and the second output terminal OutB are electrically coupled to the first signal output terminal 334 and the second signal output terminal 333 respectively. In the embodiment, the second integrated chip 3321 is an integrated chip LM4916.

The switch 35 is electrically coupled between the first source 34 and the signal amplifying circuit 33. The first source 34 powers on the detection apparatus 30. The switch 35 receives operations of a user. When the switch 35 is switched on, the detection apparatus 30 is turned on, and when the switch 36 is switched off, the detection apparatus 30 is turned off. In one embodiment, the first source 34 is a DC voltage, and the first source 34 generates a 1.5V DC voltage.

The loudspeaker 36 is driven by the second detecting signal output from the first signal output terminal 334 and the second signal output terminal 333 and gives audible warning to the user. When a sound continuously generated by the second detecting signal drops down in pitch and the range of drop is greater than a predetermined threshold, the detection apparatus 30 determines the location of the electronic wire 2 to be short circuit.

In another embodiment, the test apparatus 1 may not require the light-coupling and isolating circuit 13, and the input terminal of the inverting and amplifying circuit 16 may be electrically coupled to the pulse output terminal 113 of the signal generating circuit 11.

Although certain embodiments of the present disclosure have been specifically described, the present disclosure is not to be construed as being limited thereto. Various changes or modifications may be made to the present disclosure without departing from the scope and spirit of the present disclosure.

What is claimed is:

1. A test apparatus, comprising:
an emission apparatus providing a test signal to an electronic wire; and
an detection apparatus detecting an electromagnetic field generated by the test signal passing through the electronic wire, and generating a detecting signal according to the electromagnetic field;
wherein when the detection apparatus determines, according to the detecting signal, that a decrease in intensity of the detecting signal, along the electronic wire, is greater than a predetermined threshold, a short circuit location of the electronic wire is determined.

2. The test apparatus according to claim 1, wherein a frequency of the test signal is 400 HZ.

3. The test apparatus according to claim 1, wherein the emission apparatus comprises:
a signal generating circuit generating a rectangular pulse;
an inverting and amplifying circuit converting and amplifying the rectangular pulse into a narrow pulse; and
a first power amplifying circuit amplifying the narrow pulse to generate the test signal.

4. The test apparatus according to claim 3, wherein the emission apparatus further comprises:
a light-coupling and isolating circuit, comprising:
a light emitting block converting the rectangular pulse into an optical signal; and
a light receiving block converting the optical signal into the rectangular pulse.

5. The test apparatus according to claim 3, wherein the signal generating circuit comprises an integrated chip NE555.

6. The test apparatus according to claim 3, wherein the inverting and amplifying circuit comprises a bipolar junction transistor (BJT) configured to invert the rectangular pulse to generate the narrow pulse, an emitter of the BJT being grounded, a base of the BJT configured to receive the rectangular pulse, an collector of the BJT configured to output the narrow pulse.

7. The test apparatus according to claim 6, wherein the first power amplifying circuit comprises a field-effect transistor (FET), a first direct current (DC) voltage input terminal for receiving a first DC voltage and a first transformer, one end of a primary coil of the first transformer is electrically coupled to the first DC voltage input terminal, a source of the FET and a drain of the FET are electrically coupled in series between the other end of the primary coil of the first transformer and ground, and a gate of FET is electrically coupled to the collector of the BJT for receiving the narrow pulse to control the FET to be switched-on or switched-off, so that the narrow pulse is amplified by the first power amplifying circuit, and is coupled from the primary coil of the first transformer to the secondary coil of the first transformer to form the test signal.

8. The test apparatus according to claim 7, wherein the first power amplifying circuit further comprises a Zener diode, a cathode of the Zener diode is electrically coupled to the gate of the FET, and an anode of the Zener diode is grounded.

9. The test apparatus according to claim 7, wherein the first power amplifying circuit further comprises a diode for avoiding a damage from the first transformer to the FET when the FET is switched off, the BJT is in parallel with the secondary coil of the first transformer, and a cathode of the diode electrically coupled to the second DC voltage input terminal.

10. The test apparatus according to claim 7, wherein the first power amplifying circuit further comprises a second capacitor and a fifth resistor absorbing a peak pulse generated by the secondary coil of the first transformer, and the second capacitor and the fifth resistor are electrically coupled in series between the source of the FET and ground.

11. The test apparatus according to claim 2, wherein the emission apparatus further comprises a first voltage converting circuit providing a first direct current voltage to the signal generating circuit.

12. The test apparatus according to claim 11, wherein the first voltage converting circuit comprises:
a second transformer receiving a first alternating current (AC) voltage and converting the first AC voltage into a second AC voltage;
a first bridge rectifier converting the first DC voltage into an original DC voltage; and
a regulating block converting the original DC voltage into a second DC voltage having a predetermined value.

13. The test apparatus according to claim 11, wherein the voltage value of the second DC voltage is 12V.

14. The test apparatus according to claim 2, wherein the emission apparatus further comprises a second voltage converting circuit generating an adjustable first DC voltage for determining a testing sensitivity of the testing apparatus.

15. The test apparatus according to claim 14, wherein the second voltage converting circuit increases a voltage value of the first DC voltage to increase the testing sensitivity of the test apparatus.

16. The test apparatus according to claim 14, wherein the second voltage converting circuit reduces a voltage value of the first DC voltage to reduce the testing sensitivity of the test apparatus.

17. The test apparatus according to claim 1, wherein the detection apparatus comprises:
a detector detecting the electromagnetic field generated by the test signal passing through the electronic wire;
a signal amplifying circuit receiving a first detecting signal corresponding to the electromagnetic field, and amplifying the first detecting signal into a second detecting signal, the second detecting signal servers as a detecting signal; and
a loudspeaker notifying a user according to the second detecting signal, wherein when a sound continuously generated by the second detecting signal drops down and the range of drop is greater than a predetermined threshold, the detection apparatus determines the location of the electronic wire to be a short circuit.

18. The test apparatus according to claim 17, wherein the detection apparatus further comprises a frequency selecting circuit selecting a detecting signal generated by the electromagnetic field having a same frequency with the test signal to improve a test sensitivity, wherein the detecting signal having the same frequency with the test signal is the first detecting signal.

19. The test apparatus according to claim 18, wherein the frequency selecting circuit is a capacitor.
